(19) United States
(12) Patent Application Publication
(10) Pub. No.: US 2010/0259133 A1
(43) Pub. Date: Oct. 14, 2010

(54) ENERGY CONVERTER PRODUCED FROM FILM-FORMING AQUEOUS POLYMER DISPERSIONS, PARTICULARLY POLYURETHANE DISPERSIONS, PARTICULARLY POLYURETHANE DISPERSIONS

(75) Inventors: Werner Jenninger, Koln (DE); Sebastian Doerr, Duesseldorf (DE); Joachim Wagner, Koeln (DE); Burkhard Koehler, Zierenberg (DE)

Correspondence Address: CONNOLLY BOVE LODGE & HUTZ, LLP, P O BOX 2207, WILMINGTON, DE, 19899, US

(73) Assignee: Bayer MaterialScience AG, Leverkusen (DE)

(21) Appl. No.: 12/747,342

(22) PCT Filed: Oct. 24, 2008
(86) PCT No.: PCT/EP08/09004

§ 371 Date: Jun. 10, 2010

(30) Foreign Application Priority Data
Dec. 12, 2007 (DE) 10 2007 059 858.2

(51) Int. Cl. H01L 41/193; H01L 41/26

(52) U.S. Cl. 310/365; 29/25.35

(57) ABSTRACT

The present invention relates to compositions comprising aqueous polymer dispersions, particularly polyurethane dispersions, used for the production of energy converter, energy converters produced therefrom, and the use of such energy converters.

The present invention relates to compositions containing aqueous polymer dispersions, in particular polyurethane dispersions, which are employed for the purpose of producing energy-converters, and to energy-converters produced therefrom and to the application of energy-converters of such a type.

Converters convert electrical energy into mechanical energy, and conversely. They are employed for sensors, actuators and generators.

The basic structure of such a converter consists of a layer of the electroactive polymer, which is coated with electrodes on both sides, as described in WO 01/06575 for example. This basic structure can be employed in the most diverse configurations for the purpose of producing sensors, actuators or generators.

Various polymers are described as an electroactive layer in the state of the art; see in WO 01/06575, for example.

Polymer dispersions for producing the electroactive layer have not been described hitherto.

Polymer dispersions as starting-point for producing elastic films exhibit various advantages; in particular, they can be handled safely by virtue of the absence of relatively large quantities of solvents, and they generally do not partially dissolve plastic substrates. An extraction of solvents by suction is usually not required; moreover, working can generally proceed at temperatures between room temperature and 100° C., so that temperature-sensitive substrates can also be coated.

An object of the present invention was therefore the provision of novel elastic insulating electroactive layers for actuators, sensors and generators that exhibit advantageous properties. In particular, they are to enable simple processing and are to exhibit advantageous mechanical properties.

It has now been found that film-forming compositions based on aqueous polyurethane dispersions are well suited for the purpose of producing elastic insulating intermediate layers for actuators.

The present invention therefore provides film-forming compositions containing aqueous polymer dispersions, preferably aqueous polyurethane dispersions, for the purpose of producing actuators, sensors and generators.

The present invention further provides a process for producing actuators by using a film, foil or coating produced from an aqueous polymer dispersions, preferably an aqueous polyurethane dispersions.

The present invention further provides actuators produced using a film consisting of an aqueous polymer dispersions, preferably an aqueous polyurethane dispersions.

The present invention further provides electronic and electrical appliances, devices, apparatuses, constructional units, automated machines, components and instruments that contain corresponding actuators.

In principle, all known aqueous polyurethane dispersions can be employed in the film-forming compositions according to the invention. Preferred, however, are anionically hydrophilized and anionically/non-ionically hydrophilized polyurethane dispersions.

Polyurethane dispersions to be employed in particularly preferred manner are obtainable by

A) isocyanate-functional prepolymers consisting of
A1) organic polyisocyanates
A2) polymeric polyols with number-average molecular weights from 400 g/mol to 8000 g/mol, preferentially 400 g/mol to 6000 g/mol and particularly preferably from 600 g/mol to 3000 g/mol, and OH functionalities from 1.5 to 6, preferably 1.8 to 3, particularly preferably from 1.9 to 2.1, and
A3) optionally hydroxyl-functional compounds with molecular weights from 62 g/mol to 399 g/mol as well as
A4) optionally isocyanate-reactive, anionic or potentially anionic and/or optionally non-ionic hydrophilizing agents
being prepared, and
   B) the free NCO groups thereof then being entirely or partly converted
B1) optionally with amino-functional compounds with molecular weights from 32 g/mol to 400 g/mol and
B2) with amino-functional, anionic or potentially anionic hydrophilizing agents accompanied by chain extension, and the prepolymers being dispersed in water before, during or after step B).

Isocyanate-reactive groups are, for example, primary and secondary amino groups, hydroxy groups or thiol groups.

These aqueous polyurethane dispersions are preferably anionically hydrophilized by means of sulfonate groups and/or carboxylate groups. In particularly preferred manner, exclusively sulfonate groups are contained for the purpose of anionic hydrophilization.

In order to obtain a good sedimentation stability, the number-average particle size of the special polyurethane dispersions preferably amounts to less than 750 nm, particularly preferably less than 500 nm, determined by means of laser correlation spectroscopy.

The polyurethane dispersions preferably possess solids contents from 10 wt. % to 70 wt. %, particularly preferably 30 wt. % to 70 wt. %, most particularly preferably 30 wt. % to 65 wt. %, relative to the polyurethane contained therein.

These polyurethane dispersions preferably exhibit less than 5 wt. %, particularly preferably less than 0.2 wt. %, of uncombined organic amines, relative to the total dispersions.

If desired, the prepolymer can be entirely or partially converted into the anionic form before, during or after the dispersion process by admixture of a base.

In order to obtain an anionic hydrophilization, hydrophilizing agents have to be employed in A4) and/or B2) that exhibit at least one group that is reactive towards NCO groups, such as amino, hydroxy or thiol groups, and that furthermore exhibit —COO⁻ or —SO₃⁻ or —PO₃²⁻ as anionic groups or the entirely or partially protonated acid forms thereof as potentially anionic groups.

Compounds for anionic or potentially anionic hydrophilization are preferably employed in A4) and/or B2) that exhibit by way of anionic or potentially anionic functionality exclusively sulfonic-acid or sulfonate groups (—SO₃H or —SO₃M, with M=alkali metal or alkaline-earth metal).

Suitable polyisocyanates pertaining to component A1) are the aliphatic, aromatic or cycloaliphatic polyisocyanates with an NCO functionality greater than or equal to 2 which are known as such to a person skilled in the art.

Examples of such suitable polyisocyanates are 1,4-butylene diisocyanate, 1,6-hexamethylene diisocyanate (HDI), isophorone diisocyanate (IPDI), 2,2,4- and/or 2,4,4-trimethylhexamethylene diisocyanate, the isomeric bis(4,4′-isocyanatocyclohexyl)methanes or mixtures thereof with arbitrary isomer content, 1,4-cyclohexylene diisocyanate, 4-isocyanatomethyl-1,8-octane diisocyanate (nonane triisocyanate), 1,4-phenylene diisocyanate, 2,4- and/or 2,6-toluylene diisocyanate, 1,5-naphthylene diisocyanate, 2,2′- and/or 2,4′- and/or 4,4′-diphenylmethane diisocyanate, 1,3- and/or 1,4-bis(2-isocyanato-prop-2-yl)benzene (TMXDI), 1,3-bis(isocyanatomethyl)benzene (XDI) as well as alkyl-2,6-diisocyanatohexanoates (lysine diisocyanates) with C1-C8 alkyl groups.

In addition to the polyisocyanates mentioned above, modified diisocyanates that exhibit a functionality ≧2, with uretdione, isocyanurate, urethane, allophanate, biuret, iminooxadiazinedione or oxadiazinetrione structure, as well as mixtures of these, can also be employed proportionately.

It is preferably a question of polyisocyanates or polyisocyanate mixtures of the type mentioned above with exclusively aliphatically or cycloaliphatically bound isocyanate groups or mixtures of these and with an average NCO functionality of the mixture from 2 to 4, preferably 2 to 2.6 and particularly preferably 2 to 2.4.

In particularly preferred manner, hexamethylene diisocyanate, isophorone diisocyanate or the isomeric bis(4,4′-isocyanatocyclohexyl)methanes as well as mixtures of the aforementioned diisocyanates are employed in A1).

Polymeric polyols with a number-average molecular weight Mₙ from 400 g/mol to 8000 g/mol, preferably from 400 g/mol to 6000 g/mol and particularly preferably from 600 g/mol to 3000 g/mol, are employed in A2). These preferably exhibit an OH functionality from 1.5 to 6, particularly preferably from 1.8 to 3, most particularly preferably from 1.9 to 2.1.

Such polymeric polyols are the polyester polyols, polyacrylate polyols, polyurethane polyols, polycarbonate polyols, polyether polyols, polyester polyacrylate polyols, polyurethane polyacrylate polyols, polyurethane polyester polyols, polyurethane polyether polyols, polyurethane polycarbonate polyols and polyester polycarbonate polyols known as such in polyurethane lacquer technology. These can be employed in A2) individually or in arbitrary mixtures with one another.

Such polyester polyols are the polycondensates formed from diols and also optionally triols and tetraols and dicarboxylic and also optionally tricarboxylic and tetracarboxylic acids or hydroxycarboxylic acids or lactones. Instead of the free polycarboxylic acids, the corresponding polycarboxylic acid anhydrides or corresponding polycarboxylic acid esters of low alcohols can also be used for the purpose of preparing the polyesters.

Examples of suitable diols are ethylene glycol, butylene glycol, diethylene glycol, triethylene glycol, polyalkylene glycols such as polyethylene glycol, furthermore 1,2-propanediol, 1,3-propanediol, 1,3-butanediol, 1,4-butanediol, 1,6-hexanediol and isomers, neopentyl glycol or hydroxypivalic acid neopentyl glycol ester, with 1,6-hexanediol and isomers, 1,4-butanediol, neopentyl glycol and hydroxypivalic acid neopentyl glycol ester being preferred. In addition to these, polyols such as trimethylolpropane, glycerin, erythritol, pentaerythritol, trimethylolbenzene or trihydroxyethyl isocyanurate may also be employed.

By way of dicarboxylic acids, phthalic acid, isophthalic acid, terephthalic acid, tetrahydrophthalic acid, hexahydrophthalic acid, cyclohexanedicarboxylic acid, adipic acid, azelaic acid, sebacic acid, glutaric acid, tetrachlorophthalic acid, maleic acid, fumaric acid, itaconic acid, malonic acid, suberic acid, 2-methylsuccinic acid, 3,3-dimethylglutaric acid and/or 2,2-dimethylsuccinic acid may be employed. By way of acid-source, use may also be made of the corresponding anhydrides.

Provided that the average functionality of the polyol to be esterified is >2, additionally monocarboxylic acids, such as benzoic acid and hexanecarboxylic acid, may also be used concomitantly.

Preferred acids are aliphatic or aromatic acids of the aforementioned type. Particularly preferred are adipic acid, isophthalic acid and phthalic acid.

Hydroxycarboxylic acids that can be used concomitantly as co-reactants in the preparation of a polyester polyol with terminal hydroxyl groups are, for example, hydroxyhexanoic acid, hydroxybutyric acid, hydroxydecanoic acid, hydroxystearic acid and such like. Suitable lactones are caprolactone, butyrolactone and homologues. Caprolactone is preferred.

Likewise, polycarbonates exhibiting hydroxyl groups, preferably polycarbonate diols, with number-average molecular weights Mₙ from 400 g/mol to 8000 g/mol, preferably 600 g/mol to 3000 g/mol, can be employed in A2). These are obtainable by reaction of carbonic-acid derivatives, such as diphenyl carbonate, dimethyl carbonate or phosgene, with polyols, preferably diols.

Examples of diols of such a type are ethylene glycol, 1,2- and 1,3-propanediol, 1,3- and 1,4-butanediol, 1,6-hexanediol, 1,8-octanediol, neopentyl glycol, 1,4-bishydroxymethylcyclohexane, 2-methyl-1,3-propanediol, 2,2,4-trimethylpentanediol-1,3, dipropylene glycol, polypropylene glycols, dibutylene glycol, polybutylene glycols, bisphenol A and lactone-modified diols of the aforementioned type.

The diol component preferably contains 40 wt. % to 100 wt. % hexanediol; 1,6-hexanediol and/or hexanediol derivatives are preferred. Such hexanediol derivatives are based on hexanediol and exhibit, besides terminal OH groups, ester groups or ether groups. Such derivatives are obtainable by reaction of hexanediol with excess caprolactone or by etherification of hexanediol with itself to yield dihexylene glycol or trihexylene glycol.

Instead of, or in addition to, pure polycarbonate diols, polyether polycarbonate diols can also be employed in A2).

Polycarbonates exhibiting hydroxyl groups are preferably of linear structure.

Likewise, polyether polyols can be employed in A2).

Suitable are, for example, the polytetramethylene glycol polyethers known as such in polyurethane chemistry, such as are obtainable by polymerisation of tetrahydrofuran by means of cationic ring opening.

Likewise suitable polyether polyols are the products of addition, known as such, of styrene oxide, ethylene oxide, propylene oxide, butylene oxide and/or epichlorohydrin to difunctional or polyfunctional starter molecules. Polyether polyols, based on the at least proportionate addition of ethylene oxide to difunctional or polyfunctional starter molecules, can also be employed as component A4) (non-ionic hydrophilizing agents).

All compounds known in accordance with the state of the art can be employed as suitable starter molecules, such as, for example, water, butyl diglycol, glycerol, diethylene glycol, trimethylpropane, propylene glycol, sorbitol, ethylenediamine, triethanolamine, 1,4-butanediol.

Preferred components in A2) are polytetramethylene glycol polyethers and polycarbonate polyols or mixtures thereof, and polytetramethylene glycol polyethers are particularly preferred.

Polyols of the stated molecular-weight range with up to 20 carbon atoms, such as ethylene glycol, diethylene glycol, triethylene glycol, 1,2-propanediol, 1,3-propanediol, 1,4-butanediol, 1,3-butylene glycol, cyclohexanediol, 1,4-cyclohexanedimethanol, 1,6-hexanediol, neopentyl glycol, hydroquinone dihydroxyethyl ether, bisphenol A (2,2-bis(4-hydroxyphenyl)propane), hydrogenated bisphenol A (2,2-bis(4-hydroxycyclohexyl)propane), trimethylolpropane, trimethylolethane, glycerol, pentaerythritol as well as arbitrary mixtures thereof with one another, can be employed in A3).

Also suitable are ester diols of the stated molecular-weight range, such as α-hydroxybutyl-∈-hydroxyhexanoic acid ester, ω-hydroxyhexyl-γ-hydroxybutyric acid ester, adipic acid (β-hydroxyethyl)ester or terephthalic acid bis(β-hydroxyethyl)ester.

Furthermore, monofunctional isocyanate-reactive compounds containing hydroxyl groups can also be employed in A3). Examples of such monofunctional compounds are ethanol, n-butanol, ethylene glycol monobutyl ether, diethylene glycol monomethyl ether, diethylene glycol monobutyl ether, propylene glycol monomethyl ether, dipropylene glycol monomethyl ether, tripropylene glycol monomethyl ether, dipropylene glycol monopropyl ether, propylene glycol monobutyl ether, dipropylene glycol monobutyl ether, tripropylene glycol monobutyl ether, 2-ethylhexanol, 1-octanol, 1-dodecanol, 1-hexadecanol.

Suitable ionically or potentially ionically hydrophilizing compounds corresponding to the definition of component A4) are, for example, monohydroxycarboxylic and dihydroxycarboxylic acids, monohydroxysulfonic and dihydroxysulfonic acids, as well as monohydroxyphosphonic and dihydroxyphosphonic acids and their salts such as dimethylolpropionic acid, dimethylolbutyric acid, hydroxypivalic acid, malic acid, citric acid, glycolic acid, lactic acid, the propoxylated adduct formed from 2-butenediol and NaHSO₃, described, for example, in DE-A 2 446 440 (pages 5-9, formulae I-II).

Suitable non-ionically hydrophilizing compounds pertaining to component A4) are, for example, polyoxyalkylene ethers that contain at least one hydroxyl, amino or thiol group. Examples are the monohydroxy-functional polyalkylene oxide polyether alcohols exhibiting, on statistical average, 5 to 70, preferably 7 to 55, ethylene-oxide units per molecule, such as are obtainable in a manner known as such by alkoxylation of suitable starter molecules (e.g. in Ullmanns Encyclopädie der technischen Chemie, 4th Edition, Volume 19, Verlag Chemie, Weinheim pp. 31-38). These are either pure polyethylene oxide ethers or mixed polyalkylene oxide ethers, containing at least 30 mol %, preferably at least 40 mol %, ethylene-oxide units, relative to all alkylene-oxide units contained.

Particularly preferred non-ionic compounds are monofunctional mixed polyalkylene oxide polyethers that exhibit 40 mol % to 100 mol % ethylene-oxide units and 0 mol % to 60 mol % propylene-oxide units.

Suitable starter molecules for such non-ionic hydrophilizing agents are saturated monoalcohols such as methanol, ethanol, n-propanol, isopropanol, n-butanol, isobutanol, sec.-butanol, the isomeric pentanols, hexanols, octanols and nonanols, n-decanol, n-dodecanol, n-tetradecanol, n-hexadecanol, n-octadecanol, cyclohexanol, the isomeric methylcyclohexanols or hydroxymethylcyclohexane, 3-ethyl-3-hydroxymethyloxetane or tetrahydrofurfuryl alcohol, diethylene glycol monoalkyl ethers such as, for example, diethylene glycol monobutyl ether, unsaturated alcohols such as allyl alcohol, 1,1-dimethylallyl alcohol or oleic alcohol, aromatic alcohols such as phenol, the isomeric cresols or methoxyphenols, araliphatic alcohols such as benzyl alcohol, anisic alcohol or cinnamic alcohol, secondary monoamines such as dimethylamine, diethylamine, dipropylamine, diisopropylamine, dibutylamine, bis(2-ethylhexyl)amine, N-methyl and N-ethyl cyclohexylamine or dicyclohexylamine as well as heterocyclic secondary amines such as morpholine, pyrrolidine, piperidine or 1H-pyrazole. Preferred starter molecules are saturated monoalcohols of the aforementioned type. In particularly preferred manner, diethylene glycol monobutyl ethers or n-butanol are used as starter molecules.

Suitable alkylene oxides for the alkoxylation reaction are, in particular, ethylene oxide and propylene oxide, which may be employed in arbitrary sequence or even in a mixture in the course of the alkoxylation reaction.

Organic diamines or polyamines, such as, for example, 1,2-ethylenediamine, 1,2- and 1,3-diaminopropane, 1,4-diaminobutane, 1,6-diaminohexane, isophoronediamine, isomer mixture of 2,2,4- and 2,4,4-trimethylhexamethylenediamine, 2-methylpentamethylenediamine, diethylenetriamine, 4,4-diaminodicyclohexylmethane, hydrazine hydrate, and/or dimethylethylenediamine, may be employed as component B1).

Furthermore, compounds that exhibit, in addition to a primary amino group, also secondary amino groups or, in addition to an amino group (primary or secondary), also OH groups, may also be employed as component B1. Examples of these are primary/secondary amines such as diethanolamine, 3-amino-1-methylaminopropane, 3-amino-1-ethylaminopropane, 3-amino-1-cyclohexylaminopropane, 3-amino-1-methylaminobutane, alkanolamines such as N-aminoethylethanolamine, ethanolamine, 3-aminopropanol, neopentanolamine.

Furthermore, monofunctional isocyanate-reactive amine compounds, such as, for example, methylamine, ethylamine, propylamine, butylamine, octylamine, laurylamine, stearylamine, isononyloxypropylamine, dimethylamine, diethylamine, dipropylamine, dibutylamine, N-methylaminopropylamine, diethyl(methyl)aminopropylamine, morpholine, piperidine, or suitable substituted derivatives thereof, amidamines formed from diprimary amines and monocarboxylic acids, monoketime of diprimary amines, primary/tertiary amines, such as N,N-dimethylaminopropylamine, may also be employed as component B1).

1,2-ethylene diamine, bis(4-aminocyclohexyl)methane, 1,4-diaminobutane, isophoronediamine, ethanolamine, diethanolamine and diethylenetriamine are preferably employed.

Suitable anionically hydrophilizing compounds pertaining to component B2) are alkali-metal salts of monoaminosulfonic and diaminosulfonic acids. Examples of such anionic hydrophilizing agents are salts of 2-(2-aminoethylamino)ethanesulfonic acid, ethylenediaminepropylsulfonic or ethylenediaminebutylsulfonic acid, 1,2- or 1,3-propylenediamine-β-ethylsulfonic acid or taurine. Furthermore, the salt of cyclohexylaminopropanesulfonic acid (CAPS) from WO-A 01/88006 can be used as anionic hydrophilizing agent.

Particularly preferred anionic hydrophilizing agents B2) are those which contain sulfonate groups by way of ionic groups and two amino groups, such as the salts of 2-(2-aminoethylamino)ethylsulfonic acid and 1,3-propylenediamine-β-ethylsulfonic acid.

For the purpose of hydrophilization, use may also be made of mixtures of anionic and non-ionic hydrophilizing agents.

In a preferred embodiment for preparing the special polyurethane dispersions, components A1) to A4) and B1) to B2) are employed in the following quantities, whereby the individual quantities always add up to 100 wt. %:

5 wt. % to 40 wt. % component A1),

### 55 wt. % to 90 wt. % A2),

0.5 wt. % to 20 wt. % sum of components A3) and B1)
0.1 wt. % to 25 wt. % sum of components A4) and B2), whereby, relative to the total quantities of components A1) to A4) and B1) to B2), 0.1 wt. % to 5 wt. % anionic or potentially anionic hydrophilizing agents from A4) and/or B2) are used.

In a particularly preferred embodiment for preparing the special polyurethane dispersions, components A1) to A4) and B1) to B2) are employed in the following quantities, whereby the individual quantities always add up to 100 wt. %:

5 wt. % to 35 wt. % component A1),

### 60 wt. % to 90 wt. % A2),

0.5 wt. % to 15 wt. % sum of components A3) and B1)
0.1 wt. % to 15 wt. % sum of components A4) and B2), whereby, relative to the total quantities of components A1) to A4) and B1) to B2), 0.2 wt. % to 4 wt. % anionic or potentially anionic hydrophilizing agents from A4) and/or B2) are used.

In a most particularly preferred embodiment for preparing the special polyurethane dispersions components, A1) to A4) and B1) to B2) are employed in the following quantities, whereby the individual quantities always add up to 100 wt. %:

10 wt. % to 30 wt. % component A1),

### 65 wt. % to 85 wt. % A2),

0.5 wt. % to 14 wt. % sum of components A3) and B1)
0.1 wt. % to 13.5 wt. % sum of components A4) and B2), whereby, relative to the total quantities of components A1) to A4) and B1) to B2), 0.5 wt. % to 3.0 wt. % anionic or potentially anionic hydrophilizing agents from A4) and/or B2) are used.

The preparation of the polyurethane dispersions can be carried out in one or more stages in homogeneous phase or, in the case of multi-stage conversion, partially in disperse phase. After fully or partially implemented polyaddition consisting of A1) to A4), a dispersing, emulsifying or dissolving step takes place. Directly afterwards a further polyaddition or modification in disperse phase optionally takes place.

In this connection, use may be made of all processes known from the state of the art, such as, for example, prepolymer mixing process, acetone process or melt dispersion process. The procedure preferably accords to the acetone process.

For the preparation by the acetone process, ordinarily constituents A2) to A4) and the polyisocyanate component A1) for preparing an isocyanate-functional polyurethane prepolymer are entirely or partially charged and optionally diluted with a solvent that is miscible with water but inert towards isocyanate groups, and heated up to temperatures within the range from 50° C. to 120° C. For the purpose of accelerating the isocyanate addition reaction, the catalysts known in polyurethane chemistry may be employed.

Suitable solvents are the customary aliphatic, keto-functional solvents such as acetone, 2-butanone, which may be added not only at the start of the preparation but, optionally in portions, also later. Preferred are acetone and 2-butanone; acetone is particularly preferred. The addition of other solvents without isocyanate-reactive groups is also possible but not preferred.

Subsequently the constituents from A1) to A4) not yet added optionally at the start of the reaction are added in metered amounts.

In the course of the preparation of the polyurethane prepolymer from A1) to A4) the molar ratio of isocyanate groups to isocyanate-reactive groups generally amounts to 1.05 to 3.5, preferably 1.1 to 3.0, particularly preferably 1.1 to 2.5.

The conversion of components A1) to A4) to yield the prepolymer is effected partially or completely, but preferably completely. In this way, polyurethane prepolymers that contain free isocyanate groups are obtained, in substance or in solution.

Directly afterwards, in a further process step, if this has not yet occurred or has occurred only partially, the prepolymer obtained is dissolved with the aid of aliphatic ketones such as acetone or 2-butanone.

The conversion of components a1) to a4) to yield the prepolymer is effected partially or completely, but preferably completely. In this way, polyurethane prepolymers that contain free isocyanate groups are obtained, in substance or in solution.

In the neutralisation step for the purpose of partial or complete conversion of potentially anionic groups into anionic groups, bases such as tertiary amines, for example trialkylamines with 1 to 12, preferably 1 to 6, C atoms in each alkyl radical or alkali-metal bases such as the corresponding hydroxides are employed.

Examples of these are trimethylamine, triethylamine, methyldiethylamine, tripropylamine, N-methylmorpholine, methyldiisopropylamine, ethyldiisopropylamine and diisopropylethylamine. The alkyl radicals may, for example, also carry hydroxyl groups, as in the case of the dialkylmonoalkanolamines, alkyldialkanolamines and trialkanolamines. By way of neutralizing agents, optionally inorganic bases, such as aqueous ammonia solution or sodium hydroxide, lithium hydroxide or potassium hydroxide, are also employable.

Preferred are ammonia, triethylamine, triethanolamine, dimethylethanolamine or diisopropylethylamine as well as sodium hydroxide, lithium hydroxide or potassium hydroxide; particularly preferred are ammonia, sodium hydroxide, lithium hydroxide or potassium hydroxide.

The molar quantity of the bases generally amounts to 50 mol % and 125 mol %, preferably between 70 mol % and 100 mol %, of the molar quantity of the acid groups to be neutralised. Neutralisation may also be effected simultaneously with the dispersion process, by the dispersing water already containing the neutralizing agent.

In the course of the chain extension in step B), NH₂-functional and/or NH-functional components are converted with the isocyanate groups of the prepolymer still remaining. The chain extension/termination is preferably carried out before the dispersion in water.

Suitable components for chain extension are organic diamines or polyamines B1), such as, for example, ethylenediamine, 1,2- and 1,3-diaminopropane, 1,4-diaminobutane, 1,6-diaminohexane, isophoronediamine, isomer mixture of 2,2,4- and 2,4,4-trimethylhexamethylenediamine, 2-methylpentamethylenediamine, diethylenetriamine, diaminodicyclohexylmethane and/or dimethylethylenediamine.

Furthermore, compounds B1) that in addition to a primary amino group also exhibit secondary amino groups or in addition to an amino group (primary or secondary) also exhibit OH groups can also be employed. Examples of these are primary/secondary amines such as diethanolamine, 3-amino-1-methylaminopropane, 3-amino-1-ethylaminopropane, 3-amino-1-cyclohexylaminopropane, 3-amino-1-methylaminobutane, alkanolamines such as N-aminoethylethanolamine, ethanolamine, 3-aminopropanol, neopentanolamine are employed for the purpose of chain extension or chain termination.

For the purpose of chain termination, ordinarily use is made of amines B1) with a group that is reactive towards isocyanates, such as methylamine, ethylamine, propylamine, butylamine, octylamine, laurylamine, stearylamine, isononyloxypropylamine, dimethylamine, diethylamine, dipropylamine, dibutylamine, N-methylaminopropylamine, diethyl(methyl)aminopropylamine, morpholine, piperidine, and/or suitable substituted derivatives thereof, amidamines formed from diprimary amines and monocarboxylic acids, monoketime of diprimary amines, primary/tertiary amines, such as N,N-dimethylaminopropylamine.

If anionic hydrophilizing agents corresponding to definition B2) with NH₂ groups or NH groups are employed for the purpose of chain extension, the chain extension of the prepolymers is preferably effected before the dispersion process.

The degree of chain extension—that is to say, the equivalent ratio of NCO-reactive groups of the compounds employed for chain extension and chain termination to free NCO groups of the prepolymer—generally amounts to between 40% and 150%, preferably between 50% and 120%, particularly preferably between 60% and 120%.

The aminic components B1) and B2) can be optionally employed in water-diluted or solvent-diluted form in the process according to the invention, individually or in mixtures, whereby any sequence of addition is possible in principle.

If water or organic solvents are used concomitantly as diluents, the diluent content in the component used in B) for chain extension preferably amounts to 40 wt. % to 95 wt. %.

The dispersion process is preferably effected directly after the chain extension. For this purpose, the dissolved and chain-extended polyurethane polymer, optionally subject to strong shearing, such as, for example, strong stirring, is either charged into the dispersing water or, conversely, the dispersing water is stirred into the chain-extended polyurethane-polymer solutions. Preferably the water is added into the dissolved chain-extended polyurethane polymer.

The solvent still contained in the dispersions after the dispersing step is ordinarily subsequently removed by distillation. Removal already during the dispersion process is likewise possible.

The residual content of organic solvents in the polyurethane dispersions typically amounts to less than 10 wt. %, preferably less than 3 wt. %, relative to the entire dispersion.

The pH value of the polyurethane dispersions according to the invention typically amounts to less as 8.0, preferably less than 7.5, and in particularly preferred manner lies between 5.5 and 7.5.

The film-forming compositions according to the invention typically contain at least 10 wt. % polyurethane, relative to the solids content of all the film-forming polymers contained in the composition. Preferably, however, at least 50 wt. %, particularly preferably at least 90 wt. % and most particularly preferably at least 95 wt. %, polyurethane is contained as film-forming polymer.

If polyurethane is not employed exclusively as film-forming polymer, then furthermore other polymer dispersions may be employed concomitantly, for example based on polyesters, poly(meth)acrylates, polyepoxides, polyvinyl acetates, polyethylene, polystyrene, polybutadienes, polyvinyl chloride and/or corresponding copolymers.

The film-forming compositions may also additionally contain auxiliaries and additives besides the polymer dispersions. Examples of such auxiliaries and additives are crosslinkers, thickeners, cosolvents, thixotroping agents, stabilisers, antioxidants, light-screening agents, emulsifiers, surfactants, plasticizers, pigments, fillers and flow-control agents.

In the sense of the present invention, crosslinkers that are optionally employed bring about the formation of covalent bonds between the film-forming polymers employed, in particular polyurethanes, by which, for example, the mechanical properties can be improved. Suitable crosslinkers are, for example, blocked or unblocked polyisocyanate crosslinkers, amide-formaldehyde resins and amine-formaldehyde resins, phenol resins, aldehyde resins and ketone resins, such as, for example, phenol-formaldehyde resins, resols, furan resins, urea resins, carbamic acid ester resins, triazine resins, melamine resins, benzoguanamine resins, cyanamide resins or aniline resins. Preferred are melamine-formaldehyde resins, in which case up to 20 mol % of the melamine can be replaced by equivalent amounts of urea. Particularly preferred is methylolated melamine, for example, bimethyolmelamine, trimethyolmelamine and/or tetramethyolmelamine. As an example, the crosslinking of hydroxy-functional polyurethanes by means of isocyanate-functional structural elements may be mentioned. Such crosslinkers, such as, for example, hydrophilic polyisocyanates (described in EP-A-0 540 985), are preferably added to the polymer dispersion only shortly prior to formation of the film. Application is then preferentially effected in two-component manner, for example by means of two-component spray application. Preferably, however, the polyurethane dispersions are employed in the composition according to the invention without crosslinkers.

Besides the polymer dispersions, the film-forming compositions may additionally also contain fillers that regulate the dielectric constant of the film. Preferred is the addition of special fillers for increasing the dielectric constant, such as electrically conductive fillers or fillers with a high dielectric constant. Examples are carbon black, graphite, single-walled or multi-walled carbon nanotubes.

Additives for increasing the dielectric constant and/or for increasing the breakdown field strength can also still be added after forming the film, for example by generation of one or more further layers or for the purpose of penetrating the film.

Application of the film-forming compositions according to the invention can be effected in accordance with all forms of application known as such; mention may be made, for example, of knife coating, brushing, pouring or spraying.

A multi-layer application with optionally interpolated drying-steps is also possible in principle.

For a more rapid drying and fixing of the foams, temperatures above 30° C. are preferably utilised. Temperatures between 30° C. and 200° C. are preferred. Also useful is a two-stage or multi-stage drying with correspondingly rising temperature gradient, in order to prevent boiling of the coating. Drying is effected, as a rule, using heating and drying appliances known as such, such as (circulating-air) drying cabinets, hot air or IR radiators. Drying by conducting the coated substrate over heated surfaces, for example rollers, is also possible. The application, as well as the drying, may each be carried out discontinuously or continuously; preferred, however, is an entirely continuous process.

The film according to the invention can be provided with further layers. This may be done on one side or on both sides, in one layer or in several layers one above the other, by complete or by two-dimensionally partial coating of the film.

Suitable as carrier materials for the production of films are, in particular, glass, release paper, foils and plastics, from which the film can optionally be simply removed.

The processing of the individual layers is effected by pouring or by knife application carried out manually or by machine; printing, screen printing and injecting or spraying and dipping are also possible processing techniques. Generally, all techniques are conceivable that can be employed in the case of an application of thin layers—for example in the case of a lacquer coating.

The films consisting of the polymer dispersions exhibit a good mechanical strength and high elasticity. Typically the values of the maximum tension (tensile strength) are greater than 0.2 N/mm² (0.2 MPa), and the maximum elongation (elongation at break) is greater than 250%. The maximum tension (tensile strength) is preferably between 0.4 MPa and 50 MPa, and the elongation is preferably greater than 350%. The modulus of elasticity at an elongation of 100% preferably lies between 0.1 MPa and 10 MPa, particularly preferably between 0.5 MPa and 5 MPa (determination in accordance with DIN 53455).

After drying, the films typically have a thickness from 0.1 μm to 1500 μm, preferably 1 μm to 500 μm, particularly preferably 5 μm to 200 μm, most particularly preferably 5 μm to 50 μm.

For the purpose of constructing an energy-converter, these films (the electroactive polymer layers) are coated on both sides with electrodes, as described in WO 01/06575, for example. This basic structure can be employed in extremely diverse configurations for the purpose of producing sensors, actuators or generators.

### EXAMPLES

Unless characterised differently, all percentage figures relate to the weight.

Unless noted differently, all analytical measurements relate to temperatures of 23° C.

The determination of the solids contents was effected in accordance with DIN-EN ISO 3251.

Unless expressly stated otherwise, NCO contents were determined volumetrically in accordance with DIN-EN ISO 11909.

The monitoring for free NCO groups was carried out by means of IR spectroscopy (band at 2260 cm⁻¹).

The specified viscosities were determined by means of rotational viscosimetry in accordance with DIN 53019 at 23° C. with a rotational viscometer manufactured by Anton Paar Germany GmbH, Ostfildern, DE.

The determination of the average particle sizes (specified is the number average) of the polyurethane dispersions was effected by means of laser correlation spectroscopy (instrument: Malvern Zetasizer 1000, Malvern Inst. Limited).

The incorporation of fillers into the dispersions according to the invention was done with a SpeedMixer (model 150 FV manufactured by Hauschild & Co KG, P.O. Box 4380, D-59039 Hamm).

Measurements of the film-layer thicknesses were carried out with a mechanical calliper manufactured by Heidenhain GmbH, P.O. Box 1260, D-83292 Traunreut.

The specimens were gauged at three different points, and the average was used by way of representative measured value.

The tensile tests were performed by means of a traction machine manufactured by Zwick, model number 1455, equipped with a load cell with an overall measuring range of 1 kN in accordance with DIN 53455 at a traction speed of 50 mm/min. By way of specimens, S2 tension rods were employed. Each measurement was performed on three similarly produced specimens, and the average of the data obtained was used for the purpose of assessment. Especially for this purpose, in addition to the tensile strength TS in [MPa] and the elongation at break EB in [%], the tension T in [MPa] at 100% (=T100) and 200% (=T200) elongation were determined.

The determination of the electrical volume resistivity VR was carried out with a measuring arrangement manufactured by Keithley Instruments Inc., 28775 Aurora Road, Cleveland, Ohio 44139, phone: (440) 248 0400, (electrometer: model number 6517A; measuring head: model number 8009) and with a jointly supplied program (model number 6524: high resistance measurement software). A symmetrical square-wave voltage of +/−50 V was applied for a duration of 4 min per period for a duration of 10 periods, and the flow of current was determined. From the values of the flow of current shortly before switching of the voltage, the resistance of the test specimen in each period of the voltage was calculated and plotted against the period number. The final value of this plotting indicates the measured value of the electrical volume resistivity of the sample.

Measurements of the dielectric constant DC were performed with a measuring arrangement manufactured by Novocontrol Technologies GmbH & Co. KG, 56414 Hundsangen (measuring bridge: alpha-A analyzer, measuring head: ZGS active sample cell test interface) with a diameter of the specimens of 20 mm. In this connection a frequency range from 10⁷ to 10⁻² Hz was investigated. By way of measure of the dielectric constant of the material investigated, the real part of the dielectric constant at 10⁻² Hz was chosen.

### Substances and Abbreviations Used:

diaminosulfonate: NH₂—CH₂CH₂—NH—CH₂CH₂—SO₃Na (45% in water)
Desmophen® 2020/C2200: polycarbonate polyol, OH value 56 mg KOH/g, number-average molecular weight 2000 g/mol (Bayer MaterialScience AG, Leverkusen, DE)
PolyTHF® 2000: polytetramethylene glycol polyol, OH value 56 mg KOH/g, number-average molecular weight 2000 g/mol (BASF Ag, Ludwigshafen, DE)
PolyTHF® 1000: polytetramethylene glycol polyol, OH value 112 mg KOH/g, number-average molecular weight 1000 g/mol (BASF Ag, Ludwigshafen, DE)
Polyether LB 25: monofunctional polyether based on ethylene oxide and propylene oxide, number-average molecular weight 2250 g/mol, OH value 25 mg KOH/g (Bayer MaterialScience AG, Leverkusen, DE)
Pritex 140 product available from Degussa GmbH, 60311 Frankfurt am Main, average grain size 29 nm, BET surface area 90 m²/g, pH value 4.5 (all data for this acc. to Degussa data sheet)

### Example 1

### Polyurethane Dispersion 1

987.0 g PolyTHF® 2000, 375.4 g PolyTHF® 1000, 761.3 g Desmophen® C2200 and 44.3 g Polyether LB 25 were heated up to 70° C. in a standard stirrer. Subsequently a mixture of 237.0 g hexamethylene diisocyanate and 313.2 g isophorone diisocyanate was added at 70° C. within 5 min and stirred at 120° C. until the theoretical NCO value was attained. The finished prepolymer was dissolved with 4830 g acetone and cooled to 50° C., and subsequently a solution of 25.1 g ethylenediamine, 116.5 g isophoronediamine, 61.7 g diaminosulfonate and 1030 g water was added in metered amounts within 10 min. The further stirring time amounted to 10 min. Then dispersion was effected by addition of 1250 g water. There followed the removal of the solvent by distillation in a vacuum.

The white dispersion obtained had the following properties:

| | |
|---|---|
| Solids content: | 61% |
| Particle size (LCS): | 312 nm |
| Viscosity (viscometer, 23° C.): | 241 mPas |
| pH (23° C.): | 6.02 |
| pH (23° C.): | 7.15 |

### Example 2

### Polyurethane Dispersion 7

450 g PolyTHF® 1000 and 2100 g PolyTHF® 2000 were heated up to 70° C. Subsequently a mixture of 225.8 g hexamethylene diisocyanate and 298.4 g isophorone diisocyanate was added at 70° C. within 5 min and stirred at 100-115° C. until such time as the theoretical NCO value was fallen below. The finished prepolymer was dissolved with 5460 g acetone at 50° C., and subsequently a solution of 29.5 g ethylenediamine, 143.2 g diaminosulfonate and 610 g water was added in metered amounts within 10 min. The further stirring time amounted to 15 min. After this, dispersion was effected within 10 min by addition of 1880 g water. There followed the removal of the solvent by distillation in a vacuum, and a dispersion was obtained that was stable in storage.

| | |
|---|---|
| Solids content: | 56% |
| Particle size (LCS): | 276 nm |
| Viscosity: | 1000 mPas |

### Example 3

### Polyurethane Dispersion

1649.0 g of a polyester formed from adipic acid, hexanediol and neopentyl glycol with an average molecular weight of 1700 g/mol were heated up to 65° C. Subsequently 291.7 g hexamethylene diisocyanate were added at 70° C. within 5 min and stirred at 100-115° C. until such time as the theoretical NCO value was fallen below. The finished prepolymer was dissolved with 3450 g acetone at 50° C. and subsequently a solution of 16.8 g ethylenediamine, 109.7 g diaminosulfonate and 425 g water was added in metered amounts within 3 min. The further stirring time amounted to 15 min. After this, dispersion was effected within 10 min by addition of 1880 g water. There followed the removal of the solvent by distillation in a vacuum, and a dispersion was obtained that was stable in storage.

| | |
|---|---|
| Solids content: | 42% |
| Particle size (LCS): | 168 nm |
| Viscosity: | 425 mPas |
| pH value: | 7.07 |

### Example 4

### PUR Dispersion

82.5 g PolyTHF® 1000, 308 g PolyTHF® 2000 and 10.0 g 2-ethylhexanol were heated up to 70° C. Subsequently a mixture of 41.4 g hexamethylene diisocyanate and 54.7 g isophorone diisocyanate was added at 70° C. within 5 min and stirred at 110-125° C. until such time as the theoretical NCO value was fallen below. The finished prepolymer was dissolved with 880 g acetone at 50° C., and subsequently a solution of 3.8 g ethylenediamine, 4.6 g isophoronediamine, 26.3 g diaminosulfonate and 138 g water was added in metered amounts within 10 min. The further stirring time amounted to 15 min. After this, dispersion was effected within 10 min by addition of 364 g water. There followed the removal of the solvent by distillation in a vacuum, and a dispersion was obtained that was stable in storage.

| | |
|---|---|
| Particle size (LCS): | 181 nm |
| Viscosity: | 1300 mPas |

### Application Experiments

### Example 5

### According to the Invention

The raw materials employed were not separately degassed. The requisite quantity of 100 g of dispersion according to the invention acc. to Example 2 was weighed out in a PP beaker. From the still liquid reaction mixture, films with a wet-layer thickness of 1 mm are knife-coated onto glass plates by hand. After production, all the films are dried overnight at 30° C. in a drying cabinet and subsequently afterannealed for 5 min at 120° C. After the annealing, the films can simply be detached from the glass plate by hand.

### Example 6

### According to the Invention

The raw materials employed were not separately degassed. The requisite quantity of 100 g of dispersion according to the invention acc. to Example 2 was weighed out in a PP beaker, the appropriate quantity of 1.783 g of Printex 140 was weighed in, and then mixed within 5 min at 3000 rpm. From the still liquid reaction mixture, films with a wet-layer thickness of 1 mm are knife-coated onto glass plates by hand. After production, all the films are dried overnight at 30° C. in a drying cabinet and subsequently afterannealed for 5 min at 120° C. After the annealing the films can simply be detached from the glass plate by hand.

### Example 7

### According to the Invention

The raw materials employed were not separately degassed. The requisite quantity of 100 g of dispersion according to the invention acc. to Example 4 was weighed out in a PP beaker. From the still liquid reaction mixture, films with a wet-layer thickness of 1 mm are knife-coated onto glass plates by hand. After production, all the films are dried overnight at 30° C. in a drying cabinet and subsequently afterannealed for 5 min at 120° C. After the annealing the films can simply be detached from the glass plate by hand.

### Example 8

### Comparative Example

All the liquid raw materials were carefully degassed in a three-stage process under argon. 10 g Terathane 650 (INVISTA GmbH, D-65795 Hatterheim, Poly-THF with a molecular weight Mn=650) is weighed out in a 60 ml single-use mixing vessel (APM-Technika AG, order No. 1033152). Subsequently 0.005 g dibutyltin dilaurate (Metacure® T-12, Air Products and Chemicals, Inc.) and 6.06 g of the isocyanate N3300 (the isocyanurate trimer of HDI; product available from Bayer MaterialScience AG) are weighed in and mixed for 1 min at 3000 rpm in a SpeedMixer. The reaction product is poured onto a glass plate and drawn out with a doctor blade of wet-layer thickness of 1 mm to form a homogeneous film. The film is subsequently annealed for 16 h at 80° C.

### Example 9

### Comparative Example

All the liquid raw materials were carefully degassed in a three-stage process under argon; the carbon black was sieved through a 125 μm screen. 10 g Terathane 650 (INVISTA GmbH, D-65795 Hatterheim, Poly-THF of molecular weight Mn=650) is weighed out with 0.536 g Printex 140 in a 60 ml single-use mixing vessel (APM-Technika AG, order No. 1033152) and mixed in a SpeedMixer (product available from APM-Technika AG, CH-9435 Heerbrugg; marketing D: Hauschild; type DAC 150 FVZ) for 3 min at 3000 rpm to form a homogeneous paste. Subsequently 0.005 g dibutyltin dilaurate (Metacure® T-12, Air Products and Chemicals, Inc.) and 6.06 g of the isocyanate N3300 (the isocyanurate trimer of HDI; product available from Bayer MaterialScience AG) were weighed in and mixed for 1 min at 3000 rpm in a SpeedMixer. The reaction paste is poured onto a glass plate and drawn out with a doctor blade of wet-layer thickness of 1 mm to form a homogeneous film with a solids content of 2%. The film is subsequently annealed for 16 h at 80° C.

### Data Pertaining to the Films:

| | EB | TS | T100 | T200 | VR | |
|---|---|---|---|---|---|---|
| Films | [%] | [MPa] | [MPa] | [MPa] | [ohm cm] | DC |
| Ex. 5* | 620 | 26.6 | 2.2 | 2.7 | 7.3 * 10¹⁰ | 125 |
| Ex. 6* | 625 | 38.9 | 2.6 | 3.3 | 3.6 * 10¹⁰ | 657 |
| Ex. 7* | 1432 | 3.4 | 0.46 | 0.58 | 4.8 * 10¹¹ | 26.9 |
| Ex. 8 | 44 | 1.7 | — | — | 2.3 * 10¹¹ | 18.3 |
| Ex. 9 | 46 | 1.6 | — | — | 7.9 * 10¹¹ | 550 |

*according to the invention

In the experiments it became evident that films consisting of polyurethane dispersions offer distinct advantages in comparison with the state of the art.

Particularly advantageous with the use of the films according to the invention consisting of dispersions are the high dielectric constant and the very good mechanical properties such as: high elasticity, high elongation at tear, good suitable tension/elongation curve with low tension at moderate elongations within the operational range of the application. The objective was an elongation at break (EB) of at least 250%, preferably 350%, particularly preferably 400%, a tensile strength (TS) between 0.2 MPa and 100 MPa, preferably between 0.4 MPa and 50 MPa, additionally a very flat tension/elongation curve with tensions below 10 MPa, preferably between 0.1 MPa and 10 MPa at moderate elongations within the range around 100% to 200%, an electrical volume resistivity (VR) of more than 1*10¹⁰ ohm cm and a dielectric constant (DC) of at least 20. In the comparative examples, a tension at 100% and 200% was not measurable, since these materials already tear at 40% to 60%.

A further advantageous aspect of the use of the dispersions is their simple handling; since in this connection it is a question of a low-viscosity one-component system, no handling of reactive groups—such as, for example, free isocyanates—is required in the course of incorporating the fillers.

1-6. (canceled)

7. A converter for converting electrical energy into mechanical energy or for converting mechanical energy into electrical energy, at least comprising two electrodes and a polymer film arranged between the electrodes, wherein the polymer film is produced from an aqueous polymer dispersion, preferably an aqueous polyurethane dispersion.

8. The converter of claim 7, wherein the polymer film is produced by drying an aqueous polyurethane dispersion that originates from a prepolymerisation process with the following steps:
A) preparing isocyanate-functional prepolymers from
A1) organic polyisocyanates
A2) polymeric polyols with a molecular weight (number-average) from 400 g/mol to 8000 g/mol and with an OH functionality from 1.5 to 6 and
A3) optionally hydroxyl-functional compounds with molecular weights from 62 g/mol to 399 g/mol and
A4) optionally isocyanate-reactive, anionic or potentially anionic and optionally non-ionic hydrophilizing agents
B) entire or partial conversion of the free NCO groups of the prepolymer from A)
B1) optionally with amino-functional compounds with molecular weights from 32 g/mol to 400 g/mol and
B2) with amino-functional, anionic or potentially anionic hydrophilizing agents
wherein the prepolymers are dispersed in water before, during or after step B).

9. The converter of claim 8, wherein component A2) contains polyether polyols, preferably polytetramethylene glycol polyethers.

10. The converter of claim 8, wherein component A1) contains difunctional isocyanate structural elements, preferably difunctional aliphatic isocyanate structural elements, particularly preferably hexamethylene diisocyanate and/or isophorone diisocyanate, and, most particularly preferably, a mixture of hexamethylene diisocyanate and isophorone diisocyanate.

11. An actuator, sensor or generator comprising at least one converter of claim 7.

12. A device comprising at least one actuator, sensor or generator of claim 11.

13. The device of claim 12, wherein said device is an electronic or electrical appliance.
